(19) United States
(12) Patent Application Publication
(10) Pub. No.: US 2012/0329285 A1
(43) Pub. Date: Dec. 27, 2012

(54) GATE DIELECTRIC LAYER FORMING METHOD

(75) Inventors: Shao-Wei WANG, Taichung City (TW); Chien-Liang Lin, Taoyuan City (TW); Ying-Wei Yen, Tongxiao Township (TW); Yu-Ren Wang, Tainan City (TW)

(73) Assignee: UNITED MICROELECTRONICS CORP., HSINCHU (TW)

(21) Appl. No.: 13/165,870

(22) Filed: Jun. 22, 2011

(51) Int. Cl. H01L 21/3105; H01L 21/318; H01L 21/316

(52) U.S. Cl. 438/762; 257/E21.241; 257/E21.285; 257/E21.292

(57) ABSTRACT

A gate dielectric layer forming method is applied to a fabrication process of a metal-oxide-semiconductor field-effect transistor. The gate dielectric layer forming method includes the following steps. Firstly, a substrate is provided. Then, an interlayer is formed on the substrate. Then, a high-k dielectric layer is formed on the interlayer. A nitridation process is performed to convert the high-k dielectric layer into a nitridated high-k dielectric layer. A first low temperature post-nitridation annealing process is performed to treat the nitridated high-k dielectric layer with a first gas. Afterwards, a second low temperature post-nitridation annealing process is performed to treat the nitridated high-k dielectric layer with a second gas.

### FIELD OF THE INVENTION

The present invention relates to a gate dielectric layer forming method, and more particularly to a gate dielectric layer forming method for use in a fabrication process of a semiconductor device.

### BACKGROUND OF THE INVENTION

As the 32 nm process technology or the 28 nm process technology is gradually adopted in the semiconductor manufacturing industry, the high-k metal gate (HKMG) plays an important role in the fabrication process of a metal-oxide-semiconductor field-effect transistor (MOSFET). FIG. 1 is a schematic cross-sectional view illustrating a typical gate dielectric layer. The gate dielectric layer in a multi-layered configuration is composed of an interlayer 11 and a high-k dielectric layer 12. The interlayer 11 is formed on a surface of a silicon substrate 1. For example, the high-k dielectric layer 12 is made of hafnium dioxide (HfO₂), and the interlayer 11 is made of silicon dioxide (SiO₂). However, the gate dielectric layer composed of the hafnium dioxide (HfO₂) layer and the silicon dioxide (SiO₂) layer is still unsatisfactory. For example, the equivalent oxide thickness (EOT) is too large. Therefore, there is a need of providing a method for reducing the equivalent oxide thickness of the gate dielectric layer.

### SUMMARY OF THE INVENTION

In accordance with an aspect, the present invention provides a gate dielectric layer forming method for use in a fabrication process of a metal-oxide-semiconductor field-effect transistor. The gate dielectric layer forming method includes the following steps. Firstly, a substrate is provided. Then, an interlayer is formed on the substrate. Then, a high-k dielectric layer is formed on the interlayer. A nitridation process is performed to convert the high-k dielectric layer into a nitridated high-k dielectric layer. A first low temperature post-nitridation annealing process is performed to treat the nitridated high-k dielectric layer with a first gas. Afterwards, a second low temperature post-nitridation annealing process is performed to treat the nitridated high-k dielectric layer with a second gas.

In an embodiment, the substrate is a silicon substrate, wherein the step of forming the interlayer on the substrate is carried out by using an in-situ steam generation (ISSG) process to form a silicon dioxide layer on the silicon substrate.

In an embodiment, the step of forming the high-k dielectric layer on the interlayer is carried out by depositing a hafnium dioxide layer on the interlayer.

In an embodiment, the nitridation process is a decoupled plasma nitridation (DPN) process.

In an embodiment, the first gas is a nitrogen gas, and the first low temperature post-nitridation annealing process is carried out at a temperature range from 500° C. to 800° C. in a pressure range from 1 to 760 ton for a time period from 5 to 60 seconds.

In an embodiment, the second gas is an oxygen gas, and the second low temperature post-nitridation annealing process is carried out at a temperature range from 500° C. to 700° C. in a pressure range from 1 to 50 ton for a time period from 5 to 60 seconds.

In accordance with another aspect, the present invention provides a gate dielectric layer forming method for use in a fabrication process of a metal-oxide-semiconductor field-effect transistor. The gate dielectric layer forming method includes the following steps. Firstly, a substrate is provided. Then, an interlayer is formed on the substrate. Then, a high-k dielectric layer is formed on the interlayer. A first low temperature annealing process is performed to treat the high-k dielectric layer with a first gas. A nitridation process is performed to convert the high-k dielectric layer into a nitridated high-k dielectric layer. Afterwards, a second low temperature annealing process is performed to treat the nitridated high-k dielectric layer with a second gas.

In accordance with a further aspect, the present invention provides a gate dielectric layer forming method for use in a fabrication process of a metal-oxide-semiconductor field-effect transistor. The gate dielectric layer forming method includes the following steps. Firstly, a substrate is provided. Then, an interlayer is formed on the substrate. A first nitridation process is performed to convert the interlayer into a nitridated interlayer. A first low temperature annealing process is performed to treat the nitridated interlayer with a first gas. Then, a high-k dielectric layer is formed on the nitridated interlayer. A second nitridation process is performed to convert the high-k dielectric layer into a nitridated high-k dielectric layer. Afterwards, a second low temperature annealing process is performed to treat the nitridated high-k dielectric layer with a second gas.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic cross-sectional view illustrating a typical gate dielectric layer;

FIGS. 2A˜2E are schematic cross-sectional views illustrating a partial process flow of a gate dielectric layer forming method according to an embodiment of the present invention;

FIGS. 3A˜3E are schematic cross-sectional views illustrating a partial process flow of a gate dielectric layer forming method according to another embodiment of the present invention;

FIGS. 4A˜4F are schematic cross-sectional views illustrating a partial process flow of a gate dielectric layer forming method according to a further embodiment of the present invention.

FIG. 5 is a schematic cross-sectional view illustrating a metal-oxide-semiconductor field-effect transistor fabricated by a gate-first process; and

FIGS. 6A and 6B are schematic cross-sectional views illustrating a metal-oxide-semiconductor field-effect transistor fabricated by a gate-last process.

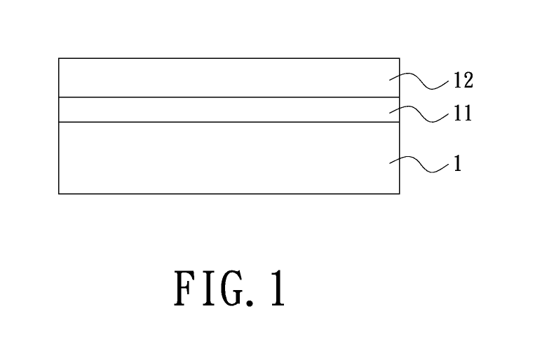

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

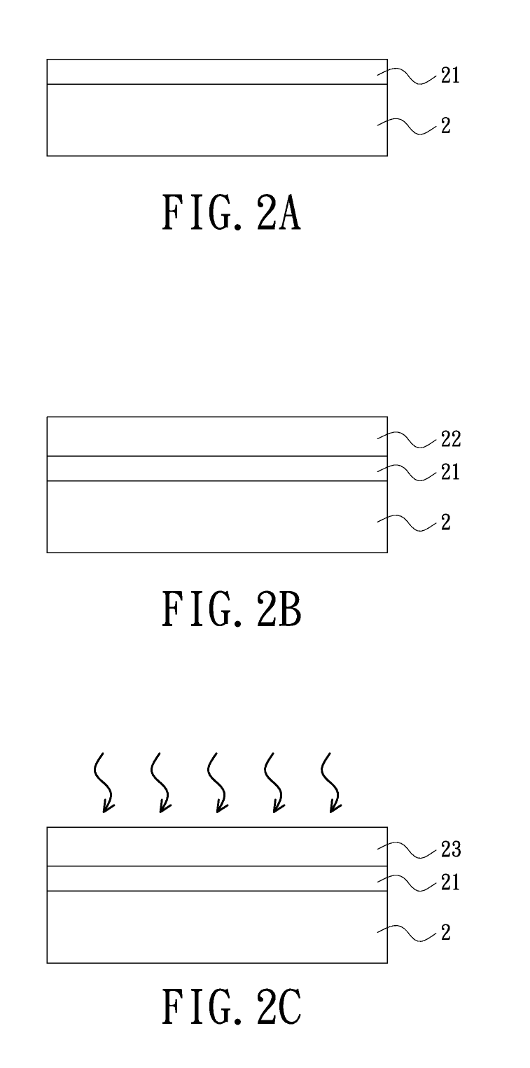

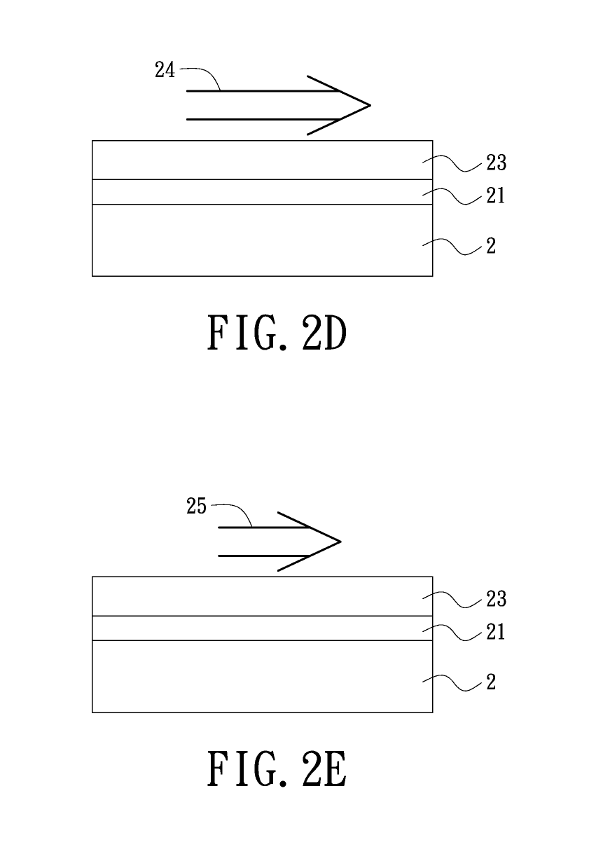

FIGS. 2A˜2E are schematic cross-sectional views illustrating a partial process flow of a gate dielectric layer forming method according to an embodiment of the present invention. The gate dielectric layer forming method may be applied to a fabrication process of a metal-oxide-semiconductor field-effect transistor (MOSFET).

Firstly, as shown in FIG. 2A, a substrate 2 (e.g. a silicon substrate) is provided. After the substrate 2 is pre-cleaned, an interlayer 21 is formed on the substrate 2. For example, the interlayer 21 is a silicon dioxide layer, and the interlayer 21 is formed on the surface of the silicon substrate 2 by a wet etching process (e.g. an in-situ steam generation (ISSG) process) or an oxidation process (e.g. a high-temperature dry oxidation process using oxygen gas as the oxidant).

Then, as shown in FIG. 2B, a high-k dielectric layer 22 is formed on the interlayer 21. For example, the high-k dielectric layer 22 is a hafnium dioxide (HfO₂) layer, and the high-k dielectric layer 22 is deposited on the interlayer 21.

Then, as shown in FIG. 2C, a nitridation process is performed to convert the high-k dielectric layer 22 into a nitridated high-k dielectric layer 23. Preferably, the nitridation plasma for performing the nitridation process is generated by a remote nitridation source, and then introduced into the process chamber. In this embodiment, the nitridation process is a decoupled plasma nitridation (DPN) process.

However, since the film quality of the nitridated high-k dielectric layer 23 may be adversely affected by the nitridation process, the following procedures will be performed to enhance the film quality. Then, as shown in FIG. 2D, a first low temperature post-nitridation annealing (PNA) process is performed by treating the nitridated high-k dielectric layer 23 with a first gas 24. The first low temperature PNA process is helpful to repair the broken bonds resulting from the decoupled plasma nitridation process, thereby improving the film quality. For example, the first gas 24 is a nitrogen gas, and the first low temperature PNA process is carried out at a temperature range from 500° C. to 800° C. in a pressure range from 1 to 760 ton for a time period from 5 to 60 seconds.

Then, as shown in FIG. 2E, a second low temperature post-nitridation annealing (PNA) process is performed by treating the nitridated high-k dielectric layer 23 with a second gas 25. For example, the second gas 25 is an oxygen gas. In this embodiment, the second low temperature PNA process is carried out at a temperature range from 500° C. to 700° C. in a pressure range from 1 to 50 ton for a time period from 5 to 60 seconds. The second low temperature PNA process is helpful to fill the oxygen vacancy of the nitridated high-k dielectric layer 23 and repair the destructive structure resulting from the decoupled plasma nitridation process. In such way, the film quality is improved.

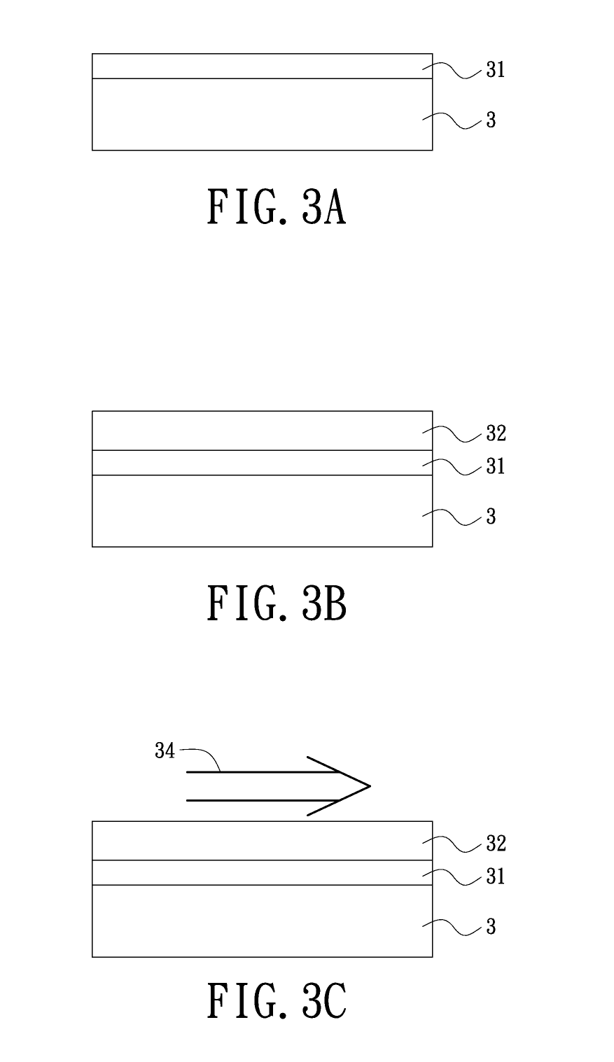

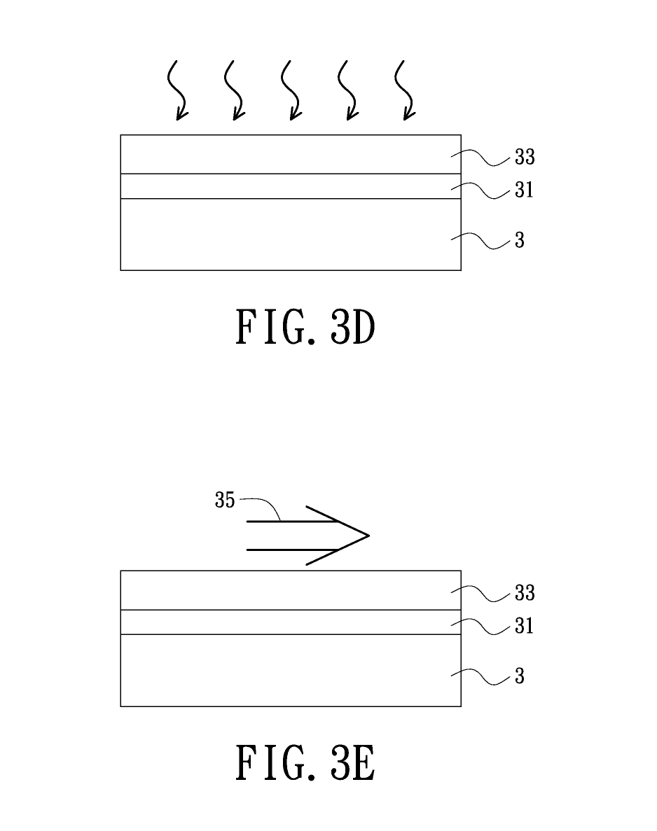

FIGS. 3A˜3E are schematic cross-sectional views illustrating a partial process flow of a gate dielectric layer forming method according to another embodiment of the present invention. The gate dielectric layer forming method may be applied to a fabrication process of a metal-oxide-semiconductor field-effect transistor (MOSFET).

Firstly, as shown in FIG. 3A, a substrate 3 (e.g. a silicon substrate) is provided. After the substrate 3 is pre-cleaned, an interlayer 31 is formed on the substrate 3. For example, the interlayer 31 is a silicon dioxide layer, and the interlayer 31 is formed on the surface of the silicon substrate 3 by a wet etching process (e.g. an in-situ steam generation (ISSG) process) or an oxidation process (e.g. a high-temperature dry oxidation process using oxygen gas as the oxidant).

Then, as shown in FIG. 3B, a high-k dielectric layer 32 is formed on the interlayer 31. For example, the high-k dielectric layer 32 is a hafnium dioxide (HfO₂) layer, and the high-k dielectric layer 32 is deposited on the interlayer 31.

Then, as shown in FIG. 3C, a first low temperature annealing process is performed to treat the high-k dielectric layer 32 with a first gas 34. The first low temperature annealing process is helpful to repair the material defect of the high-k dielectric layer 32 (e.g. a hafnium dioxide layer), thereby improving the film quality. The first gas 34 may be a nitrogen gas or an oxygen gas. In a case that the first gas 34 is a nitrogen gas, the first low temperature annealing process is carried out at a temperature range from 500° C. to 800° C. in a pressure range from 1 to 760 ton for a time period from 5 to 60 seconds. Whereas, in a case that the first gas 34 is an oxygen gas, the first low temperature annealing process is carried out at a temperature range from 500° C. to 700° C. in a pressure range from 1 to 50 ton for a time period from 5 to 60 seconds.

Then, as shown in FIG. 3D, a nitridation process is performed to convert the high-k dielectric layer 32 into a nitridated high-k dielectric layer 33. Preferably, the nitridation plasma for performing the nitridation process is generated by a remote nitridation source, and then introduced into the process chamber. In this embodiment, the nitridation process is a decoupled plasma nitridation (DPN) process.

Then, as shown in FIG. 3E, a second low temperature annealing process is performed by treating the nitridated high-k dielectric layer 33 with a second gas 35. The second gas 35 may be a nitrogen gas or an oxygen gas. In a case that the second gas 35 is an oxygen gas, the second low temperature annealing process is carried out at a temperature range from 500° C. to 700° C. in a pressure range from 1 to 50 torr for a time period from 5 to 60 seconds. Whereas, in a case that the second gas 35 is a nitrogen gas, the second low temperature annealing process is carried out at a temperature range from 500° C. to 800° C. in a pressure range from 1 to 760 torr for a time period from 5 to 60 seconds.

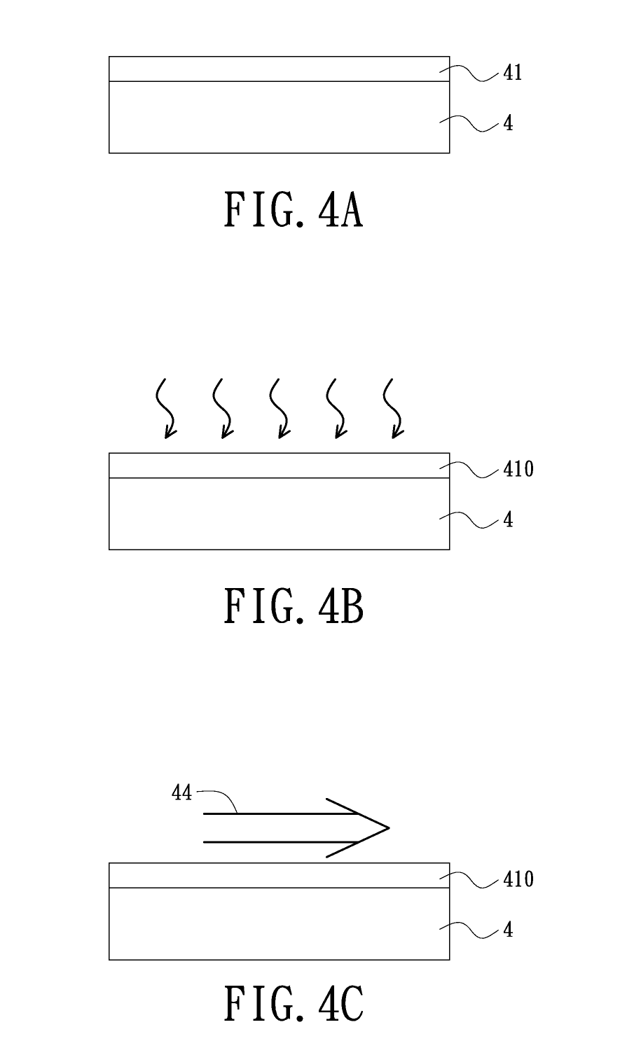

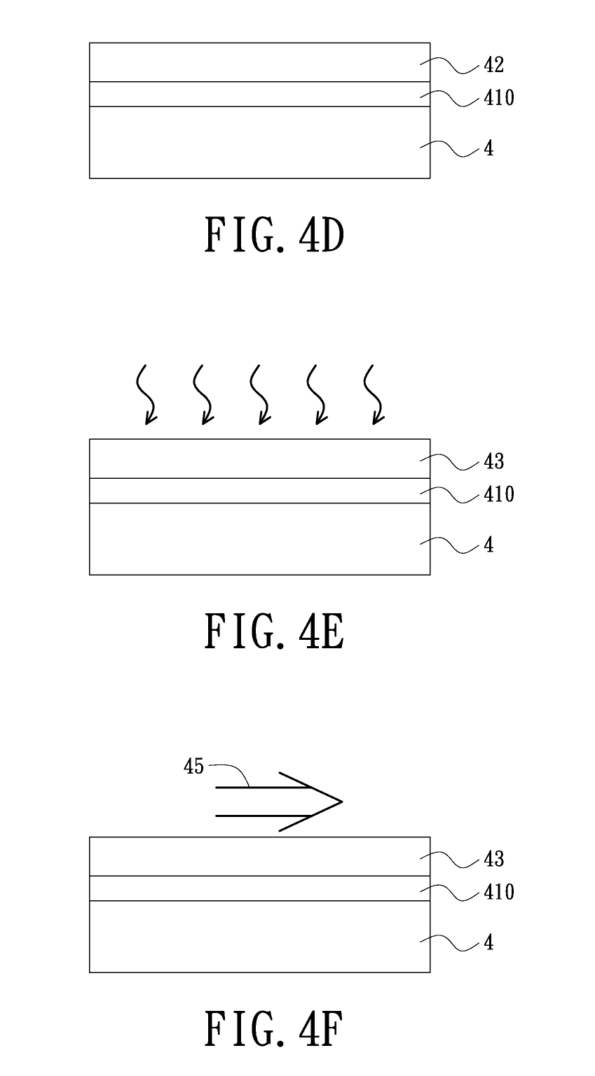

FIGS. 4A˜4F are schematic cross-sectional views illustrating a partial process flow of a gate dielectric layer forming method according to a further embodiment of the present invention. The gate dielectric layer forming method may be applied to a fabrication process of a metal-oxide-semiconductor field-effect transistor (MOSFET).

Firstly, as shown in FIG. 4A, a substrate 4 (e.g. a silicon substrate) is provided. After the substrate 4 is pre-cleaned, an interlayer 41 is formed on the substrate 4. For example, the interlayer 41 is a silicon dioxide layer, and the interlayer 41 is formed on the surface of the silicon substrate 4 by a wet etching process (e.g. an in-situ steam generation (ISSG) process) or an oxidation process (e.g. a high-temperature dry oxidation process using oxygen gas as the oxidant).

Then, as shown in FIG. 4B, a nitridation process is performed to convert the interlayer 41 into a nitridated interlayer 410 (e.g. a silicon oxynitride layer). In this embodiment, the nitridation process is a decoupled plasma nitridation (DPN) process.

Then, as shown in FIG. 4C, a first low temperature annealing process is performed to treat the nitridated interlayer 410 with a first gas 44. The first low temperature annealing process is helpful to repair the material defect of the nitridated interlayer 410, thereby improving the film quality. In a case that the first gas 44 is a nitrogen gas, the first low temperature annealing process is carried out at a temperature range from 500° C. to 800° C. in a pressure range from 1 to 760 ton for a time period from 5 to 60 seconds. Whereas, in a case that the first gas 44 is an oxygen gas, the first low temperature annealing process is carried out at a temperature range from 500° C. to 700° C. in a pressure range from 1 to 50 torr for a time period from 5 to 60 seconds.

Then, as shown in FIG. 4D, a high-k dielectric layer 42 is formed on the nitridated interlayer 410. For example, the high-k dielectric layer 42 is a hafnium dioxide (HfO₂) layer, and the high-k dielectric layer 42 is deposited on the interlayer 41.

Then, as shown in FIG. 4E, a nitridation process is performed to convert the high-k dielectric layer 42 into a nitridated high-k dielectric layer 43. Preferably, the nitridation plasma for performing the nitridation process is generated by a remote nitridation source, and then introduced into the process chamber. In this embodiment, the nitridation process is a decoupled plasma nitridation (DPN) process.

Then, as shown in FIG. 4F, a second low temperature annealing process is performed by treating the nitridated high-k dielectric layer 43 with a second gas 45. The second low temperature annealing process is helpful for improving the film quality. The second gas 45 may be a nitrogen gas or an oxygen gas. In a case that the second gas 45 is an oxygen gas, the second low temperature annealing process is carried out at a temperature range from 500° C. to 700° C. in a pressure range from 1 to 50 ton for a time period from 5 to 60 seconds. Whereas, in a case that the second gas 45 is a nitrogen gas, the second low temperature annealing process is carried out at a temperature range from 500° C. to 800° C. in a pressure range from 1 to 760 torr for a time period from 5 to 60 seconds.

After the interlayer 21, 31 or 41 and the nitridated high-k dielectric layer 23, 33 or 43 are formed in resulting structure as shown in FIG. 2E, 3E or 4F, a gate-first process or a gate-last process may be performed to a metal-oxide-semiconductor field-effect transistor.

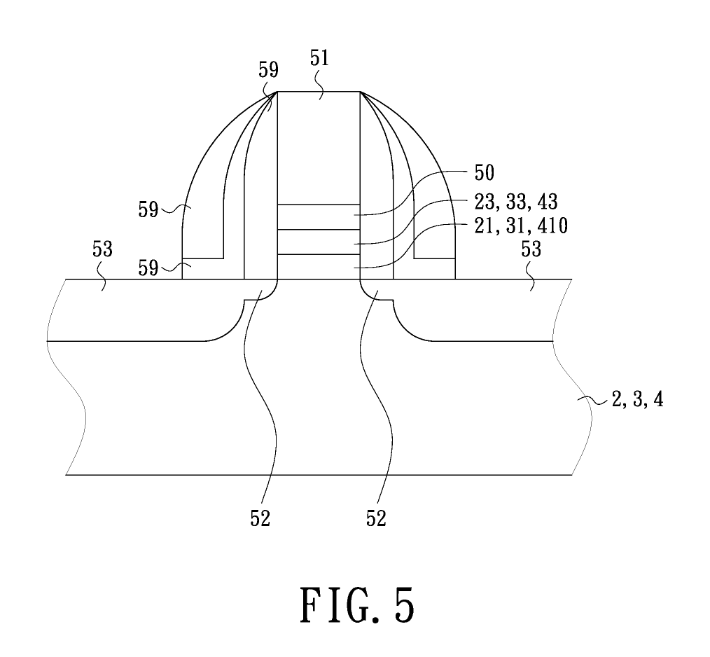

The gate-first process will be illustrated as follows. Firstly, a work function layer 50 and a silicon layer 51 are sequentially formed. Then, these layers are patterned to define a gate structure. Then, the remaining structures of the metal-oxide-semiconductor field-effect transistor are formed. For example, after a sidewall structure 59, a lightly doped drain 52 and a source/drain structure 53 are formed, the metal-oxide-semiconductor field-effect transistor as shown in FIG. 5 is fabricated.

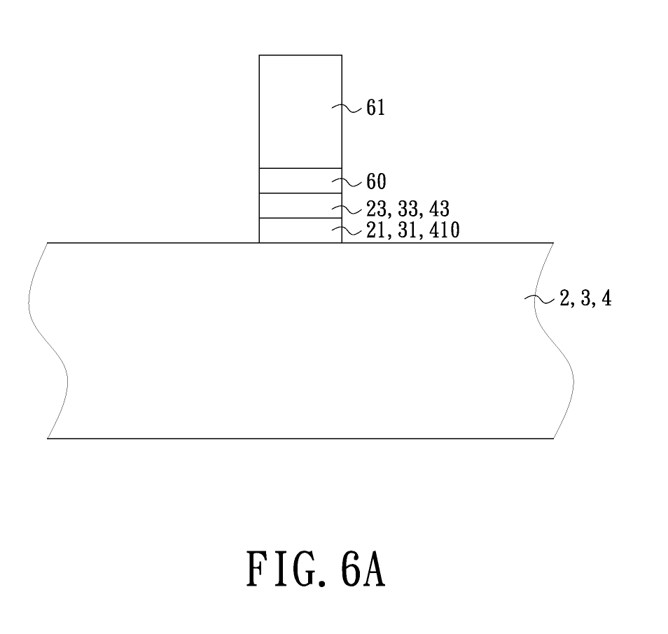

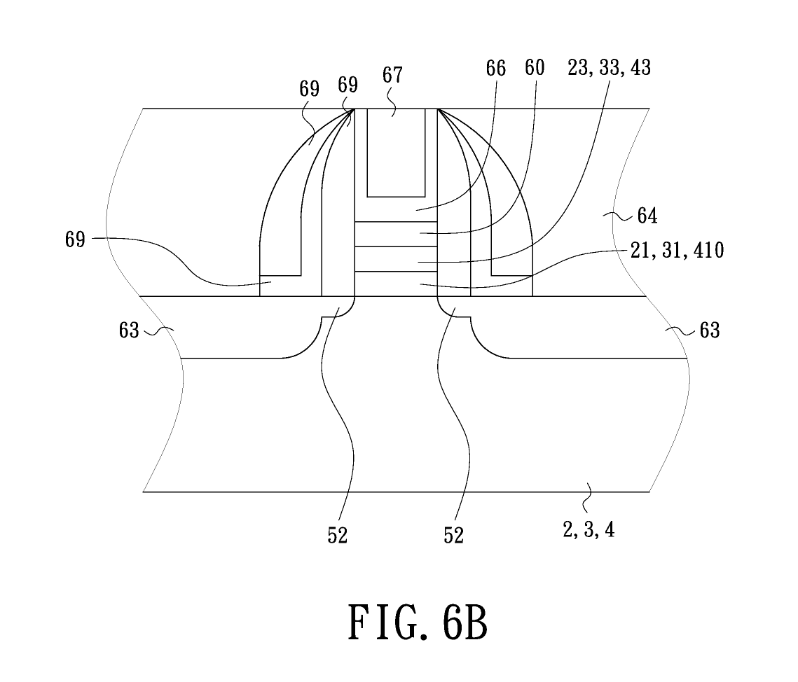

The gate-last process will be illustrated as follows. Firstly, a barrier layer/etch stop layer 60, for example made of silicon nitride (TiN) is formed. Then, a polysilicon dummy gate layer 61 is formed. Then, these layers are patterned to define a dummy gate electrode (see FIG. 6A). Then, a sidewall structure 69, a lightly doped drain 62 and a source/drain structure 63 are formed. After an interlay dielectric layer (ILD) 64 is formed, the dummy gate electrode 61 is exposed. After the dummy gate electrode 61 is removed to create a trench, a work function metal 66 and a low-resistance metal 67 are filled into the trench, thereby forming a metal gate. Consequently, metal-oxide-semiconductor field-effect transistor as shown in FIG. 6B is fabricated.

From the above description, the gate dielectric layer forming method of the present invention is capable of largely reducing the thermal budget impact and preventing crystallization of the material of the high-k dielectric layer resulting from the high temperature process. Consequently, the electrical performance can be enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A gate dielectric layer forming method for use in a fabrication process of a metal-oxide-semiconductor field-effect transistor, the gate dielectric layer forming method comprising steps of:
providing a substrate;
forming an interlayer on the substrate;
forming a high-k dielectric layer on the interlayer;
performing a nitridation process to convert the high-k dielectric layer into a nitridated high-k dielectric layer;
performing a first low temperature post-nitridation annealing process to treat the nitridated high-k dielectric layer with a first gas; and
performing a second low temperature post-nitridation annealing process to treat the nitridated high-k dielectric layer with a second gas.

2. The gate dielectric layer forming method according to claim 1, wherein the substrate is a silicon substrate, wherein the step of forming the interlayer on the substrate is carried out by using an in-situ steam generation (ISSG) process to form a silicon dioxide layer on the silicon substrate.

3. The gate dielectric layer forming method according to claim 1, wherein the step of forming the high-k dielectric layer on the interlayer is carried out by depositing a hafnium dioxide layer on the interlayer.

4. The gate dielectric layer forming method according to claim 1, wherein the nitridation process is a decoupled plasma nitridation (DPN) process.

5. The gate dielectric layer forming method according to claim 1, wherein the first gas is a nitrogen gas, and the first low temperature post-nitridation annealing process is carried out at a temperature range from 500° C. to 800° C. in a pressure range from 1 to 760 ton for a time period from 5 to 60 seconds.

6. The gate dielectric layer forming method according to claim 1, wherein the second gas is an oxygen gas, and the second low temperature post-nitridation annealing process is carried out at a temperature range from 500° C. to 700° C. in a pressure range from 1 to 50 torr for a time period from 5 to 60 seconds.

7. A gate dielectric layer forming method for use in a fabrication process of a metal-oxide-semiconductor field-effect transistor, the gate dielectric layer forming method comprising steps of:
providing a substrate;
forming an interlayer on the substrate;
forming a high-k dielectric layer on the interlayer;
performing a first low temperature annealing process to treat the high-k dielectric layer with a first gas;
performing a nitridation process to convert the high-k dielectric layer into a nitridated high-k dielectric layer; and
performing a second low temperature annealing process to treat the nitridated high-k dielectric layer with a second gas.

8. The gate dielectric layer forming method according to claim 7, wherein the substrate is a silicon substrate, wherein the step of forming the interlayer on the substrate is carried out by using an in-situ steam generation (ISSG) process to form a silicon dioxide layer on the silicon substrate.

9. The gate dielectric layer forming method according to claim 7, wherein the step of forming the high-k dielectric layer on the interlayer is carried out by depositing a hafnium dioxide layer on the interlayer.

10. The gate dielectric layer forming method according to claim 7, wherein the nitridation process is a decoupled plasma nitridation (DPN) process.

11. The gate dielectric layer forming method according to claim 7, wherein the first gas is a nitrogen gas, and the first low temperature annealing process is carried out at a temperature range from 500° C. to 800° C. in a pressure range from 1 to 760 ton for a time period from 5 to 60 seconds.

12. The gate dielectric layer forming method according to claim 7, wherein the second gas is a nitrogen gas, and the second low temperature annealing process is carried out at a temperature range from 500° C. to 800° C. in a pressure range from 1 to 760 ton for a time period from 5 to 60 seconds.

13. The gate dielectric layer forming method according to claim 7, wherein the second gas is an oxygen gas, and the second low temperature annealing process is carried out at a temperature range from 500° C. to 700° C. in a pressure range from 1 to 50 ton for a time period from 5 to 60 seconds.

14. The gate dielectric layer forming method according to claim 7, wherein the first gas is an oxygen gas, and the first low temperature annealing process is carried out at a temperature range from 500° C. to 700° C. in a pressure range from 1 to 50 ton for a time period from 5 to 60 seconds.

15. A gate dielectric layer forming method for use in a fabrication process of a metal-oxide-semiconductor field-effect transistor, the gate dielectric layer forming method comprising steps of:
providing a substrate;
forming an interlayer on the substrate;
performing a first nitridation process to convert the interlayer into a nitridated interlayer;
performing a first low temperature annealing process to treat the nitridated interlayer with a first gas;
forming a high-k dielectric layer on the nitridated interlayer;
performing a second nitridation process to convert the high-k dielectric layer into a nitridated high-k dielectric layer; and
performing a second low temperature annealing process to treat the nitridated high-k dielectric layer with a second gas.

16. The gate dielectric layer forming method according to claim 15, wherein the substrate is a silicon substrate, wherein the step of forming the interlayer on the substrate is carried out by using an in-situ steam generation (ISSG) process to form a silicon dioxide layer on the silicon substrate.

17. The gate dielectric layer forming method according to claim 15, wherein the step of forming the high-k dielectric layer on the nitridated interlayer is carried out by depositing a hafnium dioxide layer on the nitridated interlayer.

18. The gate dielectric layer forming method according to claim 15, wherein the first nitridation process and the second nitridation process are decoupled plasma nitridation (DPN) processes.

19. The gate dielectric layer forming method according to claim 15, wherein the first gas is a nitrogen gas, and the first low temperature annealing process is carried out at a temperature range from 500° C. to 800° C. in a pressure range from 1 to 760 torr for a time period from 5 to 60 seconds.

20. The gate dielectric layer forming method according to claim 15, wherein the second gas is a nitrogen gas, and the second low temperature annealing process is carried out at a temperature range from 500° C. to 800° C. in a pressure range from 1 to 760 torr for a time period from 5 to 60 seconds.

21. The gate dielectric layer forming method according to claim 15, wherein the second gas is an oxygen gas, and the second low temperature annealing process is carried out at a temperature range from 500° C. to 700° C. in a pressure range from 1 to 50 torr for a time period from 5 to 60 seconds.

22. The gate dielectric layer forming method according to claim 15, wherein the first gas is an oxygen gas, and the first low temperature annealing process is carried out at a temperature range from 500° C. to 700° C. in a pressure range from 1 to 50 torr for a time period from 5 to 60 seconds.
